(19) United States
(12) Patent Application Publication
(10) Pub. No.: US 2010/0127937 A1
(43) Pub. Date: May 27, 2010

(54) Antenna Integrated in a Semiconductor Chip

(75) Inventors: Arvind Chandrasekaran, San Diego, CA (US); Kenneth Kaskoun, La Jolla, CA (US); Shiqun Gu, San Diego, CA (US)

Correspondence Address: QUALCOMM INCORPORATED, 5775 MOREHOUSE DR., SAN DIEGO, CA, 92121, US

(73) Assignee: QUALCOMM INCORPORATED, San Diego, CA (US)

(21) Appl. No.: 12/277,447

(22) Filed: Nov. 25, 2008

(51) Int. Cl. H01Q 1/36; H01Q 23/00; H01P 11/00; H01L 21/00

(52) U.S. Cl. 343/700 MS; 29/600; 438/667; 257/E21.001

(57) ABSTRACT

An antenna structure is integrated in a semiconductor chip. The antenna structure is formed by at least one of: a) one or more through-silicon vias (TSVs), and b) one or more crack stop structures. In certain embodiments, the antenna structure includes an antenna element formed by the TSVs. The antenna structure may further include a directional element formed by the crack stop structure. In certain other embodiments, the antenna structure includes an antenna element formed by the crack stop structure, and the antenna structure may further include a directional element formed by the TSVs.

### TECHNICAL FIELD

The following description relates generally to an antenna for wireless communication, and more particularly to an antenna integrated in a semiconductor chip through use of semiconductor fabrication structures such as through-silicon vias or crack stops.

### BACKGROUND

Wireless communication devices are becoming increasingly prevalent. In general, wireless communication enables communication of information over some distance without the use of a physical carrier of the information (e.g., wires). Depending on the type of wireless communication technology employed, a device may support short-range communication (such as infrared (IR) communication used for remote controls, Bluetooth, etc.) and/or long-range communication (such as cellular telephony communication). Various types of wireless communication devices are known in the art. Examples of wireless communication devices include various types of fixed, mobile, and portable two-way radios (e.g., Professional LMR (Land Mobile Radio), SMR (Specialized Mobile Radio), Consumer Two Way Radio including FRS (Family Radio Service), GMRS (General Mobile Radio Service) and Citizens band (“CB”) radios, the Amateur Radio Service (Ham radio), consumer and professional Marine VHF radios, etc.), mobile telephones (e.g., cellular telephones, cordless telephones, etc.), pagers, personal digital assistants (PDAs), pagers, wireless handheld devices (e.g., Blackberry™ wireless handheld), global positioning system (GPS) units, wireless computer peripherals (e.g., wireless mice, keyboards, printers, etc.), wireless sensors, RFID devices, video gaming devices, and any device having a communication interface for a wireless communication protocol, such as radio frequency (RF), Bluetooth, IEEE 802.11, WiFi, etc. Wireless communication devices may support point-to-point communication, point-to-multipoint communication, broadcasting, cellular networks, and/or other wireless network communication.

In wireless communication devices, an antenna is generally included for transmitting and receiving signals. The antenna is conventionally fabricated outside of a semiconductor chip (e.g., “off-silicon”). Thus, a wireless communication device may include one or more semiconductor chips, which may include various logic for performing operations desired for the wireless communication, such as a processor and/or other logic for generating information to communicate and/or for processing received communication, as examples. In addition, the wireless communication device may further include an antenna, and the antenna is conventionally fabricated outside of the above-mentioned semiconductor chips of the device. Thus, the antenna may be referred to as being an external antenna since it is fabricated outside of a semiconductor chip rather than being an integral part of a semiconductor chip. Such an external antenna may be communicatively interfaced or coupled to one or more of the semiconductor chips in some way within the wireless communication device. Thus, conventionally the semiconductor chip and antenna are often each pre-fabricated separately, and may coupled together in a post-semiconductor-fabrication manner (i.e., after the semiconductor fabrication, such as lithography, deposition, etching, and/or other processes commonly performed for semiconductor fabrication of the chip). The external antenna conventionally occupies an undesirably large amount of space within the wireless communication device, in addition to the space consumed by the one or more semiconductor chips.

In some instances, an antenna is fabricated on a semiconductor chip. That is, in some instances an antenna may be formed on a chip during semiconductor fabrication of the chip. Conventionally, such antennas are fabricated on the silicon die by coating a large part of the die's surface. For instance, an antenna may be implemented on-chip by depositing metal on a layer of the semiconductor chip, wherein such a horizontally-oriented antenna may consume an undesirable amount of space on the surface of a layer of the chip. In addition, such an implementation requires use of metal strips that are dedicated solely for implementing an antenna.

### SUMMARY

Embodiments of the present disclosure are directed generally to an antenna structure integrated in a semiconductor chip. According to one embodiment, an integrated antenna structure implemented in an integrated circuit is provided. The integrated antenna structure comprises a semiconductor fabrication structure. In certain embodiments, the semiconductor fabrication structure comprises a through-silicon via (TSV). Additionally or alternatively, in certain embodiments, the semiconductor fabrication structure comprises a crack stop structure. In certain embodiments, the antenna structure comprises an antenna element. The antenna element may be formed by a TSV and/or crack stop structure. In certain embodiments, the antenna structure comprises a directional element. The directional element may be formed by a TSV and/or crack stop structure.

According to another exemplary embodiment, a method of fabricating an antenna structure integrated in a semiconductor chip is provided. The method includes forming a semiconductor fabrication structure to implement the antenna structure. The semiconductor fabrication structure comprises at least one of: a) one or more TSVs, and b) one or more crack stop structures.

According to still another embodiment, an integrated circuit is provided that includes a TSV and a crack stop structure. At least one of the TSV and the crack stop structure forms an antenna structure.

The foregoing has outlined rather broadly the features and technical advantages of the present invention in order that the detailed description that follows may be better understood. Additional features and advantages will be described hereinafter which form the subject of the claims of the invention. It should be appreciated by those skilled in the art that the conception and specific embodiments disclosed may be readily utilized as a basis for modifying or designing other structures for carrying out the same purposes of the present invention. It should also be realized by those skilled in the art that such equivalent constructions do not depart from the technology of the invention as set forth in the appended claims. The novel features which are believed to be characteristic of the invention, both as to its organization and method of operation, together with further objects and advantages will be better understood from the following description when considered in connection with the accompanying figures. It is to be expressly understood, however, that each of the figures is provided for the purpose of illustration and description only and is not intended as a definition of the limits of the present invention.

### BRIEF DESCRIPTION OF THE DRAWINGS

For a more complete understanding of the present invention, reference is now made to the following description taken in conjunction with the accompanying drawings.

FIG. 1A is an illustrative view showing one exemplary embodiment of a semiconductor chip having an antenna element integrated therein.

FIG. 1B is a cross-sectional view showing an exemplary technique for forming the integrated antenna element of FIG. 1A according to one embodiment.

FIG. 2 is a block diagram showing an exemplary embodiment of a semiconductor chip which includes a chip crack stop implemented thereon, wherein such chip crack stop is configured to form at least a portion of an antenna structure.

FIG. 3 is a block diagram showing another exemplary embodiment of a semiconductor chip which includes a chip crack stop implemented thereon, wherein such chip crack stop is coupled with an antenna element to extend the antenna element length.

FIGS. 4A-4C show further exemplary embodiments of semiconductor chips having an integrated antenna structure.

FIG. 5 is a flow diagram showing an exemplary operational flow for forming a semiconductor chip having an integrated antenna structure.

FIG. 6 is a block diagram showing an exemplary wireless communication system in which an embodiment of the invention may be advantageously employed.

### DETAILED DESCRIPTION

Embodiments of the present disclosure are directed generally to an antenna structure integrated in a semiconductor chip. As used herein, an antenna structure refers generally to an antenna element and/or any associated directional elements (e.g., reflectors, directors, etc.), which may aid in the efficiency of the antenna element. Thus, an “antenna structure” may refer either to an antenna element, an associated directional element, or both. For instance, in some embodiments, a chip having an integrated antenna structure may have an antenna element with no associated directional element implemented therewith, whereas in other embodiments a chip having an integrated antenna structure may include both an antenna element and an associated directional element.

Systems and methods for forming an antenna structure for wireless communication in which the antenna structure is integrated in a semiconductor chip are provided. In certain embodiments, the antenna structure is implemented in the chip through use of semiconductor fabrication structures. As used herein, “semiconductor fabrication structures” that are used for implementing an antenna structure are defined as a through-silicon via (TSV), crack stop, or both. Rather than forming an antenna structure separate from a semiconductor die (and thereafter coupling the antenna structure with a pre-fabricated semiconductor die), certain embodiments form an antenna structure when fabricating a semiconductor die such that the antenna structure is integrally formed in the semiconductor die.

Exemplary embodiments of a resulting semiconductor chip having an integrated antenna structure so formed are also described. Of course, as should be recognized by those of ordinary skill in the art, the concepts and techniques described herein are not limited to any specific implementation or configuration of an integrated antenna structure, but rather antenna structures of various different configurations (e.g., shapes, lengths, etc.) that may be desired for a given application may be formed in accordance with the concepts and techniques disclosed herein.

Certain embodiments utilize semiconductor fabrication structures present in a semiconductor chip for implementing an antenna structure. A “semiconductor fabrication structure,” as that term is used herein, refers generally to any TSV structure, crack stop structure, or both a TSV structure and crack stop structure formed during fabrication of the semiconductor chip. Thus, such semiconductor fabrication structures refer generally to structures formed on the chip during the chip's fabrication, as distinguished from structures that are formed external to or separate from the chip.

In certain embodiments, semiconductor fabrication structures serve a dual purpose of mechanically or otherwise structurally aiding in the fabrication of the semiconductor chip, as well as being leveraged for implementing an antenna structure. For instance, a crack stop may be utilized during fabrication of a semiconductor (e.g., a crack stop may be implemented about the periphery of a functional portion of a die to prevent the spread of any cracks occurring when the die is diced from the wafer into the functional portion of the die), and the crack stop may also be utilized for implementing an antenna structure on the die.

In certain embodiments, all or a portion of the semiconductor fabrication structures used for implementing an antenna structure may be used for the sole purpose of implementing an antenna, rather than also having the dual purpose of aiding in fabrication of the chip.

In one embodiment, an antenna array is constructed using a TSV in a semiconductor die or die stack. For instance, arrays of TSVs may be fabricated on a die with connecting pads on the top and bottom surfaces of the die. The die may be held singly or stacked successively on another die until a desired via length is achieved. The die may have suitable metal layer connections alternately connecting the vias in a serpentine structure (or other desired antenna configuration). In certain embodiments, no more than two metal layers are needed for implementing an antenna array in this manner. An exemplary embodiment enables a high-frequency, short-range antenna array to be constructed in this manner such that it is integrated in the semiconductor chip (e.g., using such semiconductor fabrication structures as TSVs). In one embodiment, a single die is used as the antenna, the single die being stacked on an RF die.

In certain embodiments, the die stack in which the antenna structure is implemented (e.g., by TSVs) may include or be attached to a functional die, also using TSVs. Thus, the resulting semiconductor chip may include both an active functional area (e.g., for implementing desired circuitry/logic of a wireless communication device, such as a processor and/or other logic), as well as an antenna structure.

In one exemplary embodiment, an antenna element (e.g., antenna array) is implemented by TSVs within a chip. In addition, one or more directional elements may be implemented by a crack stop structure. Such crack stop structure may be arranged about the periphery of the chip's active area, and may serve to prevent stress cracks from spreading into the chip's active area (e.g., during dicing of the chip from the wafer). In addition, the crack stop structure may be configured to serve the dual purpose of acting as a directional element for the antenna element, thereby increasing the antenna element's efficiency.

In another exemplary embodiment, an antenna element (e.g., antenna array) is implemented by a crack stop structure within a chip. In addition, one or more directional elements may be implemented by TSVs, thereby increasing the antenna element's efficiency.

Before further describing exemplary embodiments of semiconductor chips having an integrated antenna structure formed therein, common semiconductor fabrication processes are briefly discussed for illustrative purposes. It should be recognized that embodiments of the present disclosure are not limited to the illustrative semiconductor fabrication processes described herein. Instead any semiconductor fabrication process in addition to or instead of those described herein that are suitable for forming a desired semiconductor die having an integrated antenna structure formed therewith may be employed.

Semiconductor fabrication processes refer generally to processes for creating a semiconductor chip. Exemplary semiconductor fabrication processes that are commonly employed in conventional semiconductor fabrication include deposition processes, removal processes, patterning processes, and processes for modifying electrical properties. Deposition processes are conventionally employed for growing, coating, or otherwise transferring material onto a substrate (e.g., wafer) (through use of such techniques as physical vapor deposition (PVD), chemical vapor deposition (CVD), electrochemical deposition (ECD), molecular beam epitaxy (MBE), and/or atomic layer deposition (ALD) among others). Removal processes are conventionally employed for removing material from the substrate (e.g., wafer) either in bulk or selectively (through use of etch processes, chemical-mechanical planarization (CMP), etc., as examples). Patterning may include a series of processes that shape or alter the existing shape of the deposited materials, and is often referred to generally as lithography. Modification of electrical properties may be performed through doping transistor sources and drains, followed by furnace anneal or rapid thermal anneal (RTA) for activating the implanted dopants, or through reduction of dielectric constant in low-k insulating materials via exposure to ultraviolet light in UV processing (UVP), as examples. Any one or more of these, and in some instances other semiconductor fabrication processes, may be used for creating a semiconductor chip.

The term “semiconductor fabrication structure” encompasses any TSV structure, crack stop structure, or both a TSV structure and crack stop structure formed through the above-mentioned and/or other semiconductor fabrication processes that may be employed for fabricating a semiconductor chip. As discussed further herein, using such a fabrication structure for implementing an antenna structure results in a chip that has an antenna structure integrally formed therein.

One process that is sometimes used in semiconductor fabrication is formation of a through-silicon via (TSV). In general, TSV refers to a vertical hole (via) passing completely through a silicon wafer or die (or through multiple stacked dies). In many cases, the vertical hole is used for forming an electrical connection through the die. For instance, a metal strip is commonly formed in the TSV to provide an electrical connection through the die. TSV technology is commonly employed in, for example, creating three-dimensional (“3D”) packages and 3D integrated circuits. In general, a 3D package contains two or more chips (integrated circuits) stacked vertically so that they occupy less space. In many 3D packages, the stacked chips are wired together along their edges; and this edge wiring slightly increases the length and width of the package and usually requires an extra “interposer” layer between the chips. In some 3D packages, TSVs are employed in place of such edge wiring, wherein the TSVs create vertical connections through the body of the chips such that the resulting package has no added length or width.

A 3D integrated circuit (“3D IC” or “3D chip”) generally refers to a single chip constructed by stacking silicon wafers and/or dies and interconnecting them vertically so that they behave as a single device. By using TSV technology, 3D ICs can pack a great deal of functionality into a small “footprint.” In addition, critical electrical paths through the device can be drastically shortened, leading to faster operation.

Of course, TSV is not limited in application to the above-mentioned 3D packages and 3D chips, but may likewise be employed in other semiconductor chip structures. Any techniques now known or later developed for forming TSVs may be employed in accordance with embodiments of the present invention that make use of such TSVs for forming an antenna structure.

Another process commonly used in semiconductor fabrication is known as chip crack stop. As mentioned above, semiconductor chips are typically formed on a silicon wafer. The chips are typically placed adjacent to one another on the wafer, and after fabrication processes are completed, the wafer is diced by cutting the wafer along kerfs. This separates the chips from each other. The dicing processes may induce stress into the chips. This stress may cause stress cracks to form through the semiconductor chip structure. That is, cracks may spread into the active/functional areas of the individual semiconductor dies. Cracks may also form due to latent stresses in the semiconductor chip structure. Thus, crack stop structures are commonly arranged about the periphery of the active area of a die to prevent the spreading of cracks into the active area. A crack stop is typically fabricated using a ring-type structure of conductive material. Any techniques now known or later developed for forming chip crack stops may be employed in accordance with embodiments of the present invention.

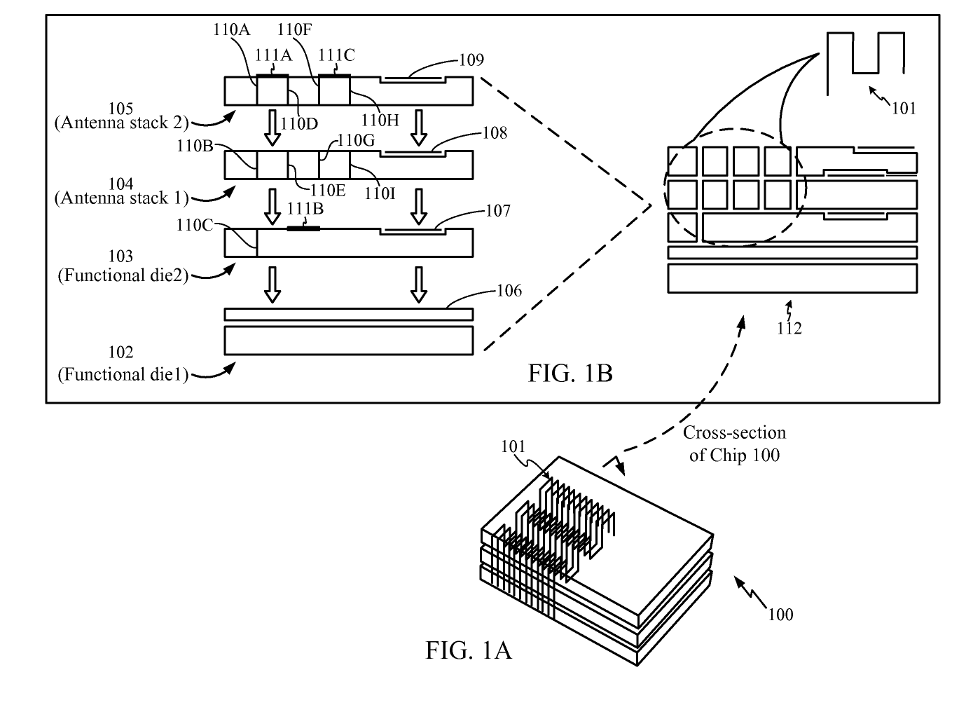

FIG. 1A shows one exemplary embodiment of a semiconductor chip 100 having an antenna element 101 integrated therein. In this exemplary embodiment, the antenna element 101 is formed by TSVs. In this example, the antenna element 101 is implemented as an antenna array, but those of ordinary skill in the art should recognize that various other antenna configurations (shapes, lengths, etc.) may be implemented in a similar manner in accordance with embodiments of the present invention.

An exemplary technique for forming such an integrated antenna element 101 according to one embodiment is shown in the corresponding cross-sectional view of FIG. 1B. FIG. 1B shows an exemplary chip fabricated using stacked dies. A first die 102 is fabricated, which in this example includes an active (or “functional”) area 106, in which circuitry desired for a given application is implemented. A second die 103 is fabricated which may also include an active area 107. Also, in this exemplary embodiment, a third die 104 and a fourth die 105 are fabricated, which may include active areas 108 and 109, respectively. Of course, in certain embodiments one or more of the dies may not include an active area.

In this exemplary embodiment of FIG. 1B, the four dies 102-105 are coupled together in a stacked configuration. In this example, TSVs are used for coupling the dies 102-105 together. In addition, the TSVs are configured to also serve as an antenna element. For instance, die 103 includes TSV 110C; die 104 includes TSVs 110B, 110E, 110G, and 110I; and die 105 includes TSVs 110A, 110D, 110F, and 110H. As shown, TSVs 110A, 110B, and 110C are vertically aligned. Similarly, TSVs 110D and 110E are vertically aligned; TSVs 110F and 110G are vertically aligned; and TSVs 110H and 110I are vertically aligned. Such TSVs may be filled with metal or other appropriate material for serving as an antenna element. In addition, horizontal elements (e.g., metal or other appropriate material for serving as an antenna element) 111A, 111B, and 111C are fabricated to couple the vertical TSVs together as shown. The resulting stack 112 of dies formed through the fabrication is shown in FIG. 1B; and an illustration of the integrated antenna element 101 formed by the TSVs is shown extracted from the resulting stack 112 for clarity.

In the above example, the dies 103-105 in which the TSVs are included for implementing the integrated antenna structure may be attached to a functional die, such as the functional die 102. Such attachment may be achieved also using TSVs, which may or may not be part of the antenna structure. Also, the fabrication steps for fabricating the dies 103-105 for forming the antenna structure can be combined with the fabrication of the functional die 102, or such dies 103-105 may be separately fabricated and attached to the functional die 102 (e.g., dies 103-105 may be obtained from a different foundry source). In addition, as shown in FIG. 1B, one or more of the dies 103-105 may also include active/functional areas, if so desired for a given chip configuration. In one embodiment, the antenna TSVs are spaced away from the active/functional areas, to reduce interference. Various configurations can be achieved in accordance with embodiments of the present disclosure, including fabrication of an antenna structure in addition to a functional die, fabrication of a standalone antenna structure die, and/or fabrication of custom antenna structure configurations.

As one exemplary application of an embodiment of a chip having an integrated antenna element 101, such as that of chip 100 of FIGS. 1A-1B, assume a target center frequency of 5 GHz is desired. In this instance, the quarter-wavelength is

$$\frac{\frac{1}{4} \times c}{5 \times {10}^{9}} = 15 mm$$

where c is the speed of light.

Compared to an unfolded antenna element, a folded antenna element has a lower efficiency, but the inefficiency resulting from folding is improved by an increase in length of the antenna element. Assuming a 2× length increase of the antenna element to compensate for folding losses, the target length for the antenna element in the above example becomes 30 millimeters (mm). Assuming TSV pitch of 20 micrometers (um) and height of 35 um, the length of one L-shaped portion of the antenna element 101 is 55 um. Thus, in this example, the number of single-line L-shaped antenna elements to be implemented equals 545 (i.e., 30 mm/55 um). Arranging in a square array, with a 20 um pitch, the 545 elements can be accommodated in 23 rows of 23 L-shaped elements each, which consumes an area of 460 um×460 um (approximately 0.5 mm×0.5 mm).

Although the example above was with respect to a target center frequency of 5 GHz, the present disclosure is not limited to such frequency. By adding additional die to the stack, the frequency can be reduced. In one embodiment, the center frequency is only 1 GHz, although again, such a frequency is a non-limiting example.

As discussed further herein, antenna gain can be improved by adding directional elements, and antenna efficiency can be improved by adding inductive/capacitive compensating elements to lower antenna reactance compared to its resistance. Assuming that compensating passive elements consume 3× antenna area, the total area consumed is approximately 0.5 mm×1.5 mm. Conventional on-chip antenna areas are typically about 7 mm×7 mm. The smallest conventional on-chip antenna is about 4 mm×4 mm, and these require special materials such as glass or special manufacturing/placement to achieve. Thus, certain embodiments of the exemplary integrated antenna structure described herein (such as that of FIGS. 1A-1B) may be utilized to enable space savings and integration of an antenna structure into existing silicon manufacturing techniques.

The exemplary embodiment of FIGS. 1A-1B illustrate use of TSVs for implementing an integrated antenna structure in a semiconductor chip. Another semiconductor fabrication structure that may be utilized in certain embodiments (either in addition to or instead of the above-mentioned TSVs) for forming an antenna structure is a chip crack stop (sometimes referred to as a die crack stop). In certain embodiments, the chip crack stop may be configured to provide a directional element (e.g., a reflector, director, etc.) for an antenna element, such as an antenna element 101 formed by TSVs as discussed above. In other embodiments, the chip crack stop may be configured to implement the antenna element instead of using TSVs to form an antenna element in the manner discussed above. In still other embodiments, the chip crack stop may be coupled with the above-described TSV antenna element, thereby extending the length of the antenna element.

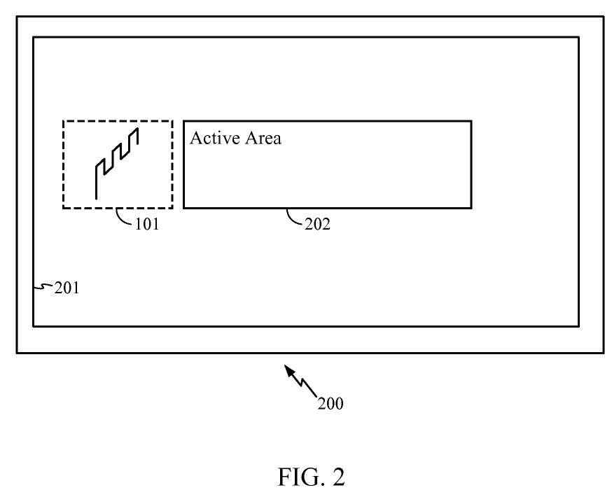

FIG. 2 shows an exemplary embodiment of a semiconductor chip 200 which includes a chip crack stop 201 implemented thereon. The chip crack stop 201 is commonly implemented about a periphery of an active area 202 of the chip 200. A crack stop is typically fabricated using a ring-type structure of conductive material. An active area 202 may include one or more of the active areas 106-109 of exemplary chip 100 of FIGS. 1A-1B discussed above, as an example. The chip crack stop 201 may include metal strips arranged to impede the progression of a crack in the silicon such that the crack does not spread into the active area 202.

Illustrative formation techniques and applications of chip crack stops can be found in U.S. Pat. Nos. 6,022,791; and 6,495,918; and in U.S. Patent Application Publication No. 2006/0220250. Of course, techniques for forming and/or using chip crack stops are not limited to those disclosed in the above-mentioned illustrative patents and published patent application, and any techniques now known or later developed for forming chip crack stops may be employed in accordance with embodiments of the present disclosure.

In certain embodiments, the chip crack stop 201 is configured to not only serve as a chip crack stop (for impeding the progression of silicon cracks into the active area 202) but also to serve as a portion of an antenna structure. In certain embodiments, the chip crack stop 201 is configured as an antenna element. For instance, the chip crack stop 201 may include a metal structure arranged in a serpentine or other suitable shape to act as an antenna element. In other embodiments, the chip crack stop 201 may be configured as a directional element for an antenna element. For instance, the chip 200 may include an antenna element 101, which may be implemented by TSVs in the manner discussed above with FIGS. 1A-1B, and the chip crack stop 201 may be configured to act as directional element(s) associated with such antenna element 101.

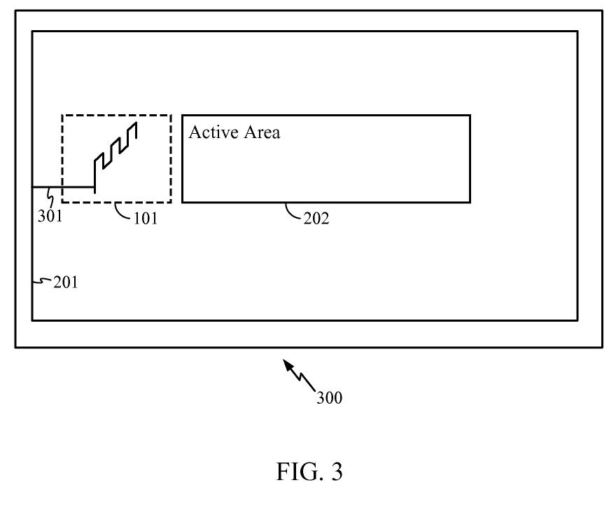

FIG. 3 shows an exemplary embodiment of a semiconductor chip 300. The chip 300 includes an antenna element 101, which may be implemented by TSVs in the manner discussed above with respect to FIGS. 1A-1B. Also, the chip 300 includes a chip crack stop 201 implemented thereon. In this exemplary embodiment, the chip crack stop 201 is coupled (e.g., via a metal trace or other suitable coupling 301) to the antenna element 101, thereby extending the length of the antenna element. That is, in this example, the chip crack stop 201 forms a portion of the length of the antenna element.

Thus, chip crack stops, such as the chip crack stop 201 of FIGS. 2-3, may be integrated into an antenna structure, in the form of: antenna element length adders (i.e., to extend the length of an antenna element), or directionality element. In a typical silicon (Si) die size of approximately 4-10 mm, the chip crack stop may be implemented to add antenna element lengths of 16-40 mm for a single loop about the periphery of the die and 48-120 mm for 3 concentric loops. Compensating for folding losses (2×), and assuming quarter-wavelength, a 30 mm single loop length (for a 7.5 mm×7.5 mm die) would imply a center frequency of 5 GHz. Thus, chip crack stops can be used in certain embodiments as an antenna element length adder or as a gain adder by adding a directional element to the TSV antenna element.

Alternatively, in certain embodiments, the chip crack stop 201 may be implemented as the main antenna element, and TSVs may be used to implement a directional/efficiency element. Thus, chip crack stops and TSVs can be used in various different tandems to create a miniaturized and integrated on-chip antenna structure.

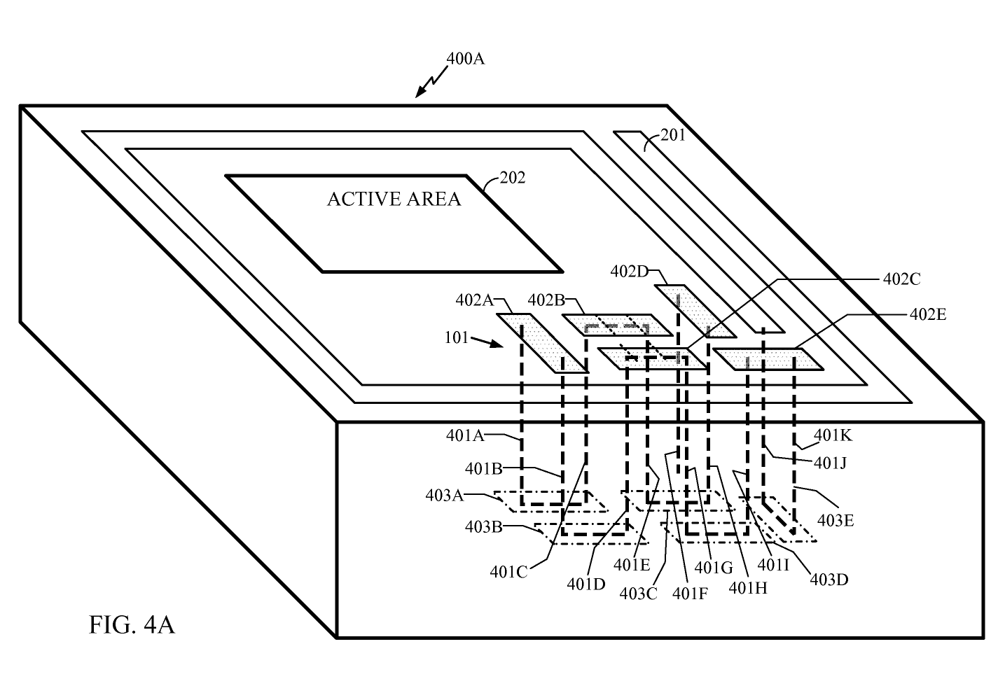

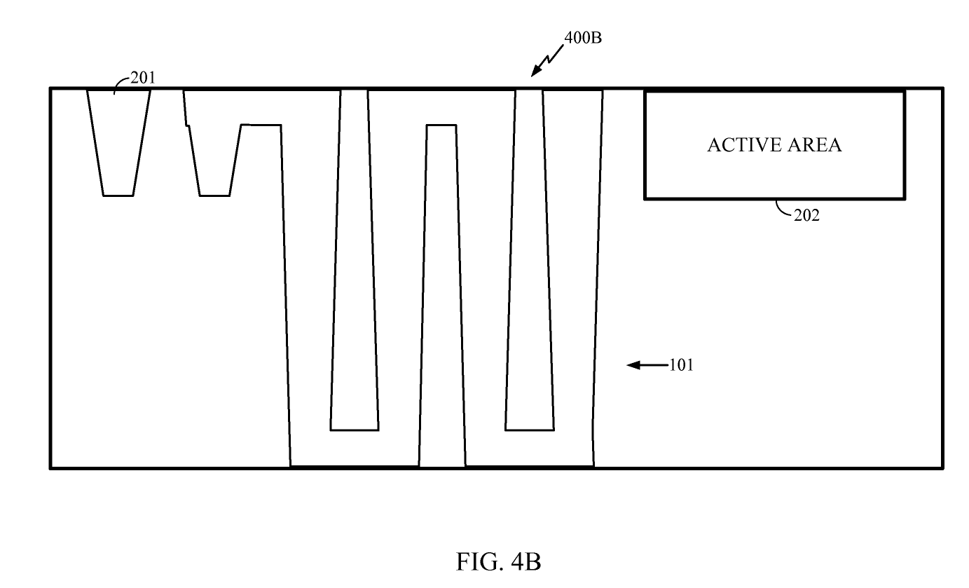

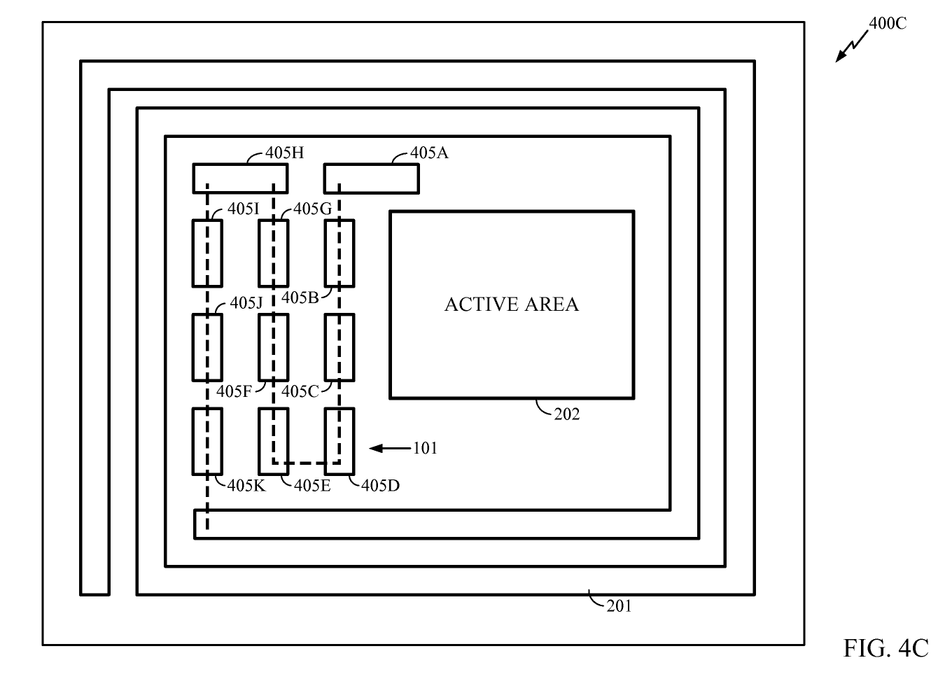

FIGS. 4A-4C show further exemplary embodiments of semiconductor chips having an integrated antenna structure. It will be understood that the exemplary embodiments of FIGS. 4A-4C may be formed through the exemplary stacking fabrication process described above with FIGS. 1A-1B. FIG. 4A shows an isometric three-dimensional view of a first embodiment of a chip 400A. As shown, the chip 400A includes an active area 202 and an integrated antenna element 101, which is implemented by TSVs 401A-401K, as shown by the hidden lines. The TSVs 401A-401K provide vertical metal elements. As illustrated in this example, the vertical metal elements formed by the TSVs 401A-401K are coupled by upper horizontal metal traces 402A-402E and by lower horizontal metal traces 403A-403E (also shown with hidden lines), thereby forming a substantially serpentine metallic structure that is integrated within the chip 400A. Also, the chip 400A includes a chip crack stop 201 implemented thereon. In this exemplary embodiment, the chip crack stop 201 is coupled (e.g., through TSV 401J) to the antenna element 101, thereby extending the length of the antenna element. That is, in this example, the chip crack stop 201 forms a portion of the length of the antenna element. Of course, in other embodiments, the chip crack stop 201 may be implemented as a directional element for the antenna element 101.

FIG. 4B shows an exemplary cross-sectional view of another embodiment of a chip 400B, illustrating a portion of an active area 202, a chip crack stop 201, and a serpentine antenna element 101 (e.g., as may be formed by the not specifically shown TSVs 401A-401K, the upper horizontal metal traces 402A-402E, and the lower horizontal metal traces 403A-403E of FIG. 4A).

FIG. 4C shows a planar view from the top of another exemplary implementation of a chip 400C, again illustrating an active area 202, a chip crack stop 201, and a serpentine antenna element 101. In this exemplary implementation, the chip crack stop 201 is longer than in the example of FIG. 4A because the chip crack stop 201 is implemented to fully encompass the outer edge of the chip 400C twice on each of the chip's four sides. Also, the exemplary implementation of the serpentine antenna element 101 is different than the exemplary structure shown in FIG. 4A. In the example of FIG. 4C, upper horizontal metal traces 405A-405K are shown, and the dashed lines indicate that TSVs are used in a manner similar to that shown in FIG. 4A for forming vertical metallic elements. Also, as shown in the example of FIG. 4A, lower horizontal metal traces are included to couple the vertical metallic elements formed by the TSVs together. Thus, the upper horizontal metal traces 405A-405K, the vertical metallic elements formed by the TSVs, and the lower horizontal metal traces together form a serpentine antenna element (similar to that shown in FIG. 4A) in the pattern indicated in FIG. 4C in this exemplary implementation of the chip 400C. Of course, various other patterns may be implemented in a similar manner for forming the integrated antenna element in other embodiments.

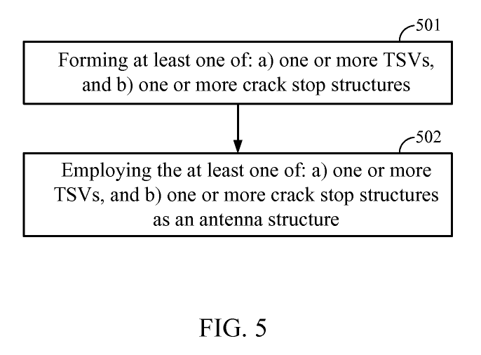

FIG. 5 shows an exemplary method for forming a semiconductor chip having an integrated antenna structure. In block 501, semiconductor fabrication is performed for forming at least one of: a) one or more TSVs, and b) one or more crack stop structures. In block 502, at least one of the a) one or more TSVs, and b) one or more crack stop structures is employed as an antenna structure. That is, in the forming block 501, the TSVs and/or crack stop structures are configured in a manner to serve as at least a portion of an antenna structure. For instance, as mentioned above, the TSVs and/or crack stop structures may each be configured to serve as an antenna element or as a directional element of an antenna structure.

Certain embodiments of the present disclosure enable an antenna structure to be integrated into a semiconductor chip. Through integration on silicon, space savings may be achieved compared to a planar antenna implemented on a system board, package substrate or silicon. The exemplary concepts and techniques disclosed herein may be employed to create large antenna arrays and/or antennas having a wide variety of shapes to achieve desirable transmission characteristics for a given application. Further, in certain embodiments, minimal contact/travel losses are encountered due to integration of the antenna structure on silicon. Also, certain embodiments afford flexibility to combine different antenna configurations with different sources of supply. And, certain embodiments enable an integrated antenna structure to be achieved in a semiconductor chip through use of existing manufacturing/semiconductor fabrication methods. Those of ordinary skill in the art should recognize that such an integrated antenna structure is suitable for use in a wide variety of applications, particularly for many high frequency/short range wireless communication applications.

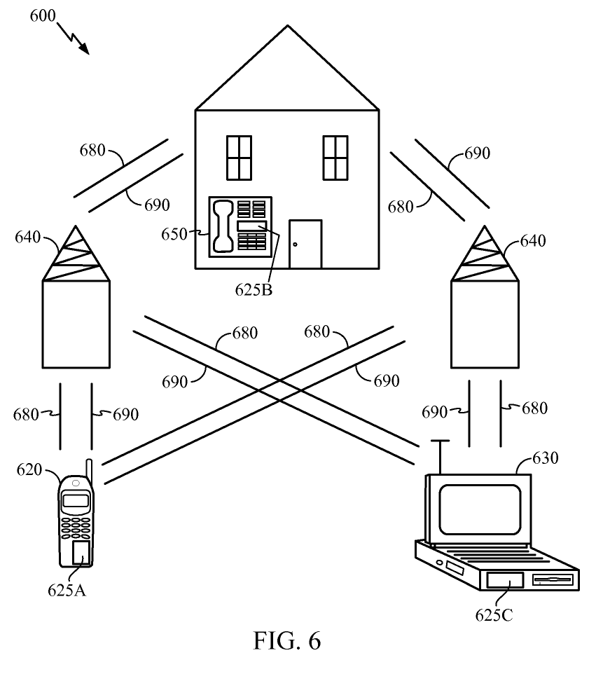

FIG. 6 shows an exemplary wireless communication system 600 in which an embodiment of an integrated antenna structure may be advantageously employed. For purposes of illustration, FIG. 6 shows three remote units 620, 630, and 650 and two base stations 640. It should be recognized that typical wireless communication systems may have many more remote units and base stations. Remote units 620, 630, and 650 may include semiconductor chips having an integrated antenna structure such as disclosed herein above. FIG. 6 shows forward link signals 680 from the base stations 640 and the remote units 620, 630, and 650 and reverse link signals 690 from the remote units 620, 630, and 650 to base stations 640.

In FIG. 6, remote unit 620 is shown as a mobile telephone, remote unit 630 is shown as a portable computer, and remote unit 650 is shown as a fixed location remote unit in a wireless local loop system. For example, the remote units may be cell phones, hand-held personal communication systems (PCS) units, portable data units such as personal data assistants, or fixed location data units such as meter reading equipment. Although FIG. 6 illustrates certain exemplary remote units that may include a chip having an integrated antenna structure in accordance with the teachings of the invention, the invention is not limited to these exemplary illustrated units. Embodiments of the invention may likewise be suitably employed in any wireless communication device in which an antenna is desired.

Although the present invention and its advantages have been described in detail, it should be understood that various changes, substitutions and alterations can be made herein without departing from the technology of the invention as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure, processes, machines, manufacture, compositions of matter, means, methods, or steps, presently existing or later to be developed that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. An integrated antenna structure implemented in an integrated circuit, the integrated antenna structure comprising:
a semiconductor fabrication structure.

2. The antenna structure of claim 1 wherein the semiconductor fabrication structure comprises a through-silicon via (TSV).

3. The antenna structure of claim 2 wherein the semiconductor fabrication structure comprises a crack stop structure.

4. The antenna structure of claim 1 wherein the semiconductor fabrication structure comprises a crack stop structure.

5. The antenna structure of claim 1 wherein the antenna structure comprises an antenna element.

6. The antenna structure of claim 5 wherein the antenna element comprises a serpentine shape.

7. The antenna structure of claim 5 wherein the antenna element is formed by a crack stop structure.

8. The antenna structure of claim 5 wherein the antenna structure further comprises a directional element.

9. The antenna structure of claim 1 wherein the semiconductor fabrication structure comprises both a TSV and a crack stop structure.

10. The antenna structure of claim 9 wherein said TSV and said crack stop structure are coupled together to form an antenna element.

11. The antenna structure of claim 1 wherein the antenna structure comprises a directional element.

12. The antenna structure of claim 11 wherein the directional element is formed by a crack stop structure.

13. The antenna structure of claim 11 wherein the directional element is formed by a TSV.

14. The antenna structure of claim 1 wherein the semiconductor fabrication structure comprises a TSV arranged in an active area of the integrated circuit and a crack stop structure are arranged at least partially around a periphery of the active area.

15. The integrated circuit of claim 1 comprising:
a first die;
a second die stacked on the first die; and
a plurality of TSVs implemented in the first and second dies to form an antenna structure.

16. The integrated circuit of claim 15 wherein the antenna structure is electrically coupled with circuitry implemented on the first die.

17. A method of fabricating an antenna structure integrated in a semiconductor chip, said method comprising:
forming a semiconductor fabrication structure;
wherein said forming comprises forming said semiconductor fabrication structure to implement said antenna structure.

18. The method of claim 17 wherein said semiconductor fabrication structure comprises at least one of: a) one or more through-silicon vias (TSVs), and b) one or more crack stop structures.

19. The method of claim 17 wherein the forming comprises forming one or more TSVs to implement an antenna element of the antenna structure.

20. The method of claim 19 further comprising:
forming one or more crack stop structures to implement a directional element of the antenna structure.

21. The method of claim 17 wherein the forming comprises forming one or more crack stop structures to implement an antenna element of the antenna structure.

22. The method of claim 21 further comprising:
forming one or more TSVs to implement a directional element of the antenna structure.
